(19) United States
(12) Patent Application Publication
(10) Pub. No.: US 2022/0337244 A1
(43) Pub. Date: Oct. 20, 2022

(54) OPTICAL POWER FOR ELECTRONIC SWITCHES

(71) Applicant: LASERMOTIVE, INC., Kent, WA (US)

(72) Inventors: Thomas J. NUGENT, Bellevue, WA (US); Thomas W. BASHFORD, Renton, WA (US)

(21) Appl. No.: 17/760,731

(22) PCT Filed: Sep. 16, 2020
(86) PCT No.: PCT/US2020/051101

§ 371 Date: Mar. 15, 2022

Related U.S. Application Data
(60) Provisional application No. 62/901,107, filed on Sep. 16, 2019.

(51) Int. Cl. H03K 17/785; H03K 17/16

(52) U.S. Cl. CPC H03K 17/785; H03K 17/162; H03K 2217/0081

(57) ABSTRACT

Various embodiments provide a laser power beaming system that delivers power via high intensity light, such as from a laser, using either power over fiber or free space power to isolate (or eliminate) high frequency noise and electromagnetic interference (EMI) due to, for example, switching. Damage or other harms from the EMI may be prevented. The opto-isolated power may be delivered from a remote source, or within a switched device, such as a variable frequency drive (VFD), itself.

### BACKGROUND

### Technical Field

The present disclosure generally relates to providing optical power for isolation of electric components.

### Description of the Related Art

Several problems are well understood in the operation of inverters (including those that drive Variable Frequency Drives, aka VFDs) and other devices that vary the input frequency and voltage supplied to electric induction motors. These problems include EMI (Electromagnetic Interference), switching speed, size, and other factors. Of particular concern is Electromagnetic Interference.

Electromagnetic Interference (EMI) is a disturbance generated by an external source that affects an electrical circuit by electromagnetic induction, electrostatic coupling, or conduction. Such a disturbance from an external source may degrade or stop the performance of the circuit. With respect to a data path, these EMI disturbances can range from an increase in error rate to a total loss of the data. Notably, EMI disturbances may be man-made or of natural origin. Changing electrical currents and voltages that can cause EMI includes, by way of example only, and not by way of limitation: ignition systems, cellular network of mobile phones, arc discharges, lightning, solar flares, and auroras.

Problems with EMI occur in a broad cross-section of use cases and applications. Problems associated with current VFD designs occur when conductive elements (copper for instance) connect sensitive or critical devices, such as solid state and other switches. Some of the issues created by inverter (e.g., VFD) EMI in inductive motors include (but are not limited to) insulation breakdown, premature motor failure, motor overheating, potential voltage and current spike damage to sensitive control equipment or other unrelated equipment on the same electrical power circuit, and damage to high performance III-V semiconductor switches.

EMI also can have significant impact on the internal function and components within the VFD. Transformers and other components have inherent capacitance, which can couple electrical noise from one electrical line to another.

Significant research and development has been applied to the increase of high switching speeds applied to inverter design. High switching speeds decrease harmonics and improve output motor performance. Some of these benefits include lowered motor losses, reduced motor heating, reduced output noise, and higher maximum motor speed. However high switching speeds can be limited by the materials used in IGBTs (Insulated-Gate Bipolar Transistors). Hence the recent development push to introduce wide bandgap (including III-V) materials to inverter design.

Wide Band Gap Semiconductor (WBGS) switches have several benefits over silicon. Those include greater efficiency, and reduced cost, size, and weight. However, inverter switches made from Wide Band Gap Semiconductors (WBGS) are susceptible to EMI.

Using SiC (silicon carbide) and GaN (gallium nitride) materials in switches (such as IGBTs) enables higher speed, but devices made using these materials may be more voltage sensitive than traditional (mainly silicon) devices. As an example, a silicon device might operate at 10V but be robust against input voltages up to 30V. But in this example, a GaN device might need 5V but only be robust against inputs up to 6V. The switching harmonics and EMI can potentially create brief voltages that are too high for these (SiC, GaN) devices.

### BRIEF SUMMARY

The present disclosure is directed to a power beaming system, either via optical fiber or free space, that provides electrically isolated power in a small form factor. Electrical power may be delivered optically and projected as light from a high intensity light source, such as a laser, to a receiver (most often including one or more photovoltaic cells) that converts the light back into electricity. Power transmitted via an optical element is generally immune to, and does not couple or generate Electromagnetic Interference (EMI).

In one or more embodiments, a wireless optical power system includes one or more laser transmitters, one or more photoreceptor receivers, a thermal management system that may be integrated within the laser power transmitter or may also be a separate thermal management system in the inverter or power receiver, one or more control systems for the transmitter and the receiver, and a light-conductive element (fiber, light tube, or air, for example) in between the transmitter and receiver.

In some embodiments, a device includes a plurality of electrical switching elements, a plurality of drivers, and a converter. The plurality of drivers are electrically coupled to the plurality of electrical switching elements, and the plurality of drivers are configured to change operating states of the plurality of electrical switching elements. The converter includes a plurality of photovoltaic (PV) modules configured to receive a plurality of light beams and convert the plurality of light beams into electrical signals for the plurality of drivers. The plurality of PV modules being electrically isolated from each other.

In another aspect of some embodiments, the device further includes a laser power transmitter configured to receive an electrical power signal, and transmit the plurality of light beams in response to receiving the electrical power signal, the converter receives the plurality of light beams from the laser power transmitter. In still another aspect of some embodiments, the plurality of light beams have electrical characteristics corresponding to the electrical power signal. In yet another aspect of some embodiments, the device further includes a transmission medium, the plurality of light beams being transmitted from the laser power transmitter, through the transmission medium, and to the converter. In some embodiments, the transmission medium is an optical fiber. In another aspect of some embodiments, the laser power transmitter includes optics configured to shape, split, reflect, or refract the plurality of light beams. In yet another aspect of some embodiments, each of the plurality of PV modules includes at least one photovoltaic cell configured to convert light into electricity, and the device further includes a plurality of power management and distribution modules electrically coupled to the plurality of PV modules.

In another aspect of one or more embodiments, the device further includes a laser power transmitter and an optical splitter. The laser power transmitter is configured to receive an electrical power signal, and transmit a light beam in response to receiving the electrical power signal. The optical splitter is configured to receive the transmitted light beam, and split the transmitted light beam into the plurality of light beams. In still another aspect of one or more embodiments, the device further includes mirrors configured to redirect the plurality of light beams towards the plurality of PV modules. In yet another aspect of one or more embodiments, the device further includes an optical element configured to collimate the transmitted light beam. In another aspect of the device, the optical splitter is configured to collimate the transmitted light beam. In still another aspect of the device, the optical splitter is a pyramidal mirror.

Referring now to another aspect of some embodiments, the device further includes a first substrate, a second substrate, and a third substrate. The first substrate includes a first PV module of the plurality of PV modules that is positioned on the first substrate. The second substrate includes a second PV module of the plurality of PV modules that is positioned on the second substrate. The third substrate including the first substrate, the second substrate, and the optical splitter are positioned on the third substrate. The first and second substrates extend in a first direction, and the third substrate extends in a third direction transverse to the first direction.

In another aspect of one or more embodiments, the device further includes a controller, a multiplexer, a laser power transmitter, and a demultiplexer. The controller is configured to generate a plurality of control signals for the plurality of drivers. The multiplexer is configured to receive the plurality of control signals, and transmit a control signal of the plurality of control signals. The laser power transmitter is configured to receive the control signal, and transmit a light beam in response to receiving the control signal. Additionally, the converter is configured to receive the first light beam from the laser power transmitter, and convert the light beam into an electrical signal. Furthermore, the demultiplexer is configured to receive the electrical signal, and route the electrical signal to the plurality of drivers.

Referring now to still another embodiment, an optical power system includes a laser transmitter, a power receiver, and a non-conductive optical fiber cable. The laser transmitter is configured to emit a light beam. The power receiver includes two or more photovoltaic modules configured to receive the light beam. The non-conductive optical fiber cable includes one or more optical fibers. The optical fiber cable is configured to transmit the light beam from the laser transmitter to the two or more photovoltaic modules. The power receiver has two or more power outputs that are electrically isolated from each other. In one or more other embodiments of the optical power system, there is not a conductive path between the laser transmitter and the power receiver.

In one or more other embodiments, a power receiver includes a plurality of photovoltaic (PV) receiver legs, wherein each PV receiver leg includes a PV module configured to convert an optical input to an electrical output, and wherein each member of the plurality of PV receiver legs is electrically isolated from each other member of the plurality.

In one or more embodiments of the power receiver, each PV module includes at least one PV cell. In another embodiment of the power receiver, at least one PV module comprises a plurality of PV cells. In still another embodiment, the power receiver further includes an optical element configured to: receive an incoming light beam; and direct at least a portion of the received incoming light beam onto a member of the plurality of PV receiver legs. In yet another embodiment of the power receiver, the optical element includes a beam splitter configured to direct a portion of the incoming light beam onto each member of the plurality of PV receiver legs. In some embodiments of the power receiver, the optical element is further configured to collimate the directed light beam. In other embodiments of the power receiver, the optical element is further configured to reshape the incoming light beam.

In one or more embodiments, the power receiver further includes an optical fiber configured to direct an optical input toward one or more members of the plurality of PV receiver legs. In some embodiments of the power receiver, the plurality of PV receiver legs are mounted on a common substrate. In other embodiments of the power receiver, the PV modules of each member of the plurality of PV receiver legs are mounted on the common substrate. In still other embodiments of the power receiver, the PV modules of each member of the plurality of PV receiver legs are mounted on a separate substrate, each separate substrate positioned at an oblique angle to the common substrate. In yet other embodiments of the power receiver, at least one of the PV receiver legs includes a power management and distribution (PMAD) component.

In another embodiment, the power transmission system includes a power receiver and a light source. The power receiver includes a plurality of photovoltaic (PV) receiver legs, wherein each PV receiver leg includes a PV module configured to convert an optical input to an electrical output, and wherein each member of the plurality of PV receiver legs is electrically isolated from each other member of the plurality. The light source is configured to provide an optical input to the power receiver. In some embodiments, the power transmission system further includes a transmission element configured to conduct the optical input from the light source to the power receiver. In other embodiments of the power transmission system, the transmission element is an optical fiber. In still other embodiments, the power transmission system further includes a multiplexer configured to encode a control signal into the optical input. In yet other embodiments, the power transmission system further includes a controller configured to create the control signal for encoding by the multiplexer.

In some embodiments of the power transmission system, at least one member of the plurality of PV receiver legs includes a demultiplexer configured to extract the encoded control signal from the electrical output of its PV module. In other embodiments of the power transmission system, each member of the plurality of PV receiver legs includes a demultiplexer configured to extract the encoded control signal from the electrical output of its PV module. In still other embodiments of the power transmission system, each demultiplexer is configured to identify a portion of the encoded control signal that pertains to its own PV receiver leg. In yet other embodiments, the power transmission system further includes a driver for controlling an electrical component, wherein the driver is configured to receive the extracted control signal from the demultiplexer and to use the received control signal to drive the electrical component.

In some embodiments, the electrical component is a switch. In another aspect of power transmission system, the power receiver and the light source are enclosed in a common housing. In still another aspect of power transmission system, the power receiver and the light source are separated by a distance of less than one meter. In yet another aspect of power transmission system, the power receiver and the light source are separated by a distance of more than five meters. In other aspects of power transmission system, the power receiver and the light source are separated by a distance of more than one kilometer.

Referring now to a method of providing electrical power to a group of electrical components, the method includes: directing an optical power beam toward a plurality of photovoltaic (PV) receiver legs, each PV receiver leg including a PV module and being associated with an electrical component; and receiving the optical power beam at the plurality PV receiver legs, wherein each PV module of the plurality of PV receiver legs (1) converts a portion of the optical power beam into a local electrical output and (2) provides the local electrical output to power the electrical component associated with its PV receiver leg, wherein the electrical component associated with each PV receiver leg is electrically isolated from electrical components associated with other PV receiver legs.

In some embodiments, each PV module includes at least one PV cell. In other embodiments, at least one PV module includes a plurality of PV cells. In still other embodiments, at least one electrical component includes a switch. In other embodiments, the method further includes modulating the optical power beam to provide a control signal for the electrical components. In yet other embodiments at least one PV receiver leg includes a demultiplexer. The method further includes: extracting the control signal from the local electrical output using the demultiplexer; and using the control signal to control the electrical component.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale.

FIG. 1 is a laser power beaming system according to an embodiment disclosed herein.

FIG. 2 is a laser power transmitter according to an embodiment disclosed herein.

FIG. 3 is a power receiver according to an embodiment disclosed herein.

FIG. 4 is a power receiver according to another embodiment disclosed herein.

FIG. 5 shows a laser light being split into separate beams according to an embodiment disclosed herein.

FIG. 6A shows receiver optics according to an embodiment disclosed herein.

FIG. 6B shows receiver optics according to another embodiment disclosed herein.

FIG. 7 shows a laser power transmitter and a power receiver according to another embodiment disclosed herein.

FIG. 8A is a laser and a photovoltaic module according to an embodiment disclosed herein.

FIG. 8B is a laser and a photovoltaic module according to another embodiment disclosed herein.

FIG. 9 shows a laser light being split into separate beams according to an embodiment disclosed herein.

FIG. 10A is a laser power beaming system with a single demultiplexer according to another embodiment disclosed herein.

FIG. 10B is a laser power beaming system with two demultiplexers according to another embodiment disclosed herein.

FIG. 11A is a driver and a switches according to an embodiment disclosed herein.

FIG. 11B is drivers and a switches according to another embodiment disclosed herein.

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of manufacturing light emitting devices, light sensors, drivers, integrated circuits, and electrical components (e.g., transistors, resistors, capacitors, switches, etc.) have not been described in detail to avoid obscuring the descriptions of other aspects of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same aspect. Furthermore, the particular features, structures, or characteristics may be combined in any suitable manner in one or more aspects of the present disclosure.

Prior to setting forth the embodiments however, it may be helpful to an understanding thereof to first set forth definitions of certain terms that are used hereinafter.

Reference throughout the specification to integrated circuits is generally intended to include integrated circuit components built on semiconducting or glass substrates, whether or not the components are coupled together into a circuit or able to be interconnected.

The term power beam is used, in all its grammatical forms, throughout the present disclosure and claims to refer to a high-flux light transmission that may include a field of light, that may be generally directional, that may be arranged for steering/aiming to a suitable receiver. The power beams discussed in the present disclosure include beams formed by high-flux laser diodes or other like sources sufficient to deliver a desirable level of power to a remote receiver without passing the power over a conventional electrical conduit such as wire.

In the present disclosure, the term “light,” when used as part of a light-based transmitter or a light-based receiver refers to a transmitter or receiver arranged to produce or capture, as the case may be, electromagnetic radiation that falls within the range of frequencies that can be directed (e.g., reflected, refracted, filtered, absorbed, captured, and the like) by optical or quasi-optical elements, and which is defined in the electromagnetic spectrum spanning from extremely low frequencies (ELF) through gamma rays, and which includes at least ultraviolet light, visible light, long-, mid- and short-wavelength infrared light, terahertz radiation, millimeter waves, microwaves, other visible and invisible light, light beams, and light transmitted within a fiber. A “beam” of light, as that term is used herein, may include both a beam transmitted through free space and a guided beam such as one transmitted through an optical fiber.

In the present disclosure, the term “optics” may be used to identify optical elements which may shape, split, reflect, refract, or otherwise modify a light beam. When present in an embodiment, “optics” may identify a single component or multiple components.

It is noted that the dimensions set forth herein are provided as examples. Other dimensions are envisioned for this embodiment and all other embodiments of this application.

As discussed above, the operation of inverters, including those that drive VFDs, causes problems such as Electromagnetic Interference. Electromagnetic Interference can have significant impact on the internal function and components within a VFD. Transformers have inherent capacitance, which can couple electrical noise from one electrical line to another.

A transformer with four separate windings is a design that is generally somewhat large (on the order of four inches on a side). Due to the proximity of the windings to each other, coupling between separate legs of the transformer can occur, which creates EMI/fluctuations that can propagate back through the electronic supply to other powered devices in the same electrical grid, and may also cause problems in the VFD motor itself.

The (normally four) separate legs are floating at different voltages relative to each other. These legs may be connected to four separate windings on a transformer, each winding going to a different leg: three for the high voltage ends of the device, and one for the ground voltage end which is common to all three legs of the device. The switching noise may propagate through the windings and to the other legs, as well as back up the input power line.

Some of the methods that are currently used to reduce the impact of these problems include creating sufficient distance between internal components to reduce potential inductive coupling between conductive elements, upstream and downstream “filtering” electronics to reduce EMI impacts, physically placing the EMI producing elements a significant distance from the load, special considerations to the cable lengths to and from the load, special construction of motors to reduce bearing damage from EMI, and cable shielding and shielding of components.

Although the foregoing modifications mitigate the EMI issues, the modifications do not sufficiently solve the problem of EMI and some even introduce new problems and design challenges.

The present disclosure generally relates to power beaming. More particularly, but not exclusively, the present disclosure relates to providing optically-isolated electrical power to multiple, electrically isolated, electrical switches.

In one or more embodiments, a laser power beaming system (which can include either the laser beam delivered wirelessly through free space, or delivered through an optical fiber) can deliver multiple, electrically isolated power outputs to power multiple electronic switches with independent, floating voltages. In one or more embodiments, if the optical power is delivered by optical fiber, the optical fiber cable is a dielectric or non-conductive. Some existing high power laser fibers include a conductive wire or shell to indicate that a fiber is plugged in and has not been broken; such cables are not preferred unless there is an adequate gap in the conductive wire or shell to keep the transmitter electrically isolated from the receiver and to keep the power outputs of the receiver electrically isolated from one another.

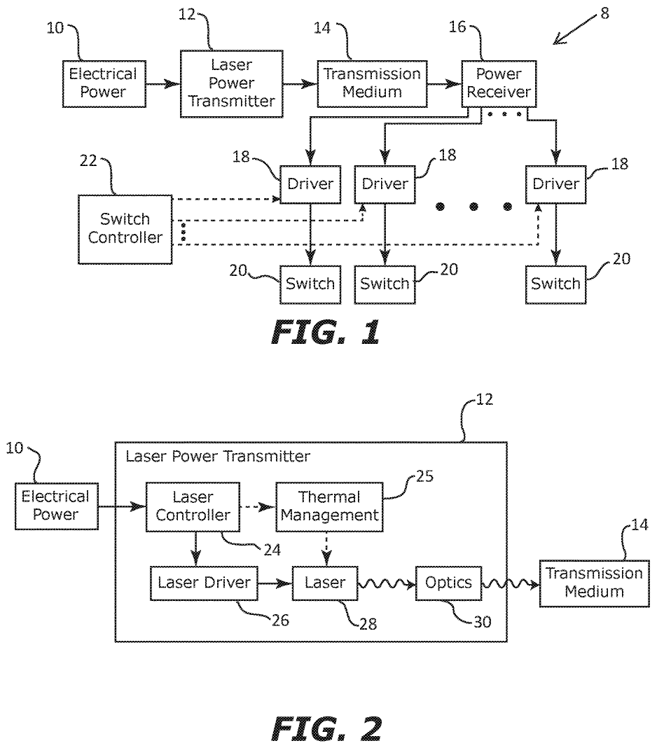

FIG. 1 is a laser power beaming system 8 according to an embodiment disclosed herein. In FIG. 1, electrical power 10 (which could be direct current (DC) or alternating current (AC), for example from a standard 120V AC outlet) energizes a laser power transmitter 12, which may include one or more laser drivers and one or more lasers.

The optical output of the laser(s) is then coupled (often using optics, for example as shown in FIG. 2) into an optical transmission medium 14, generally either an optical fiber or free space, positioned at an output of the laser power transmitter 12. In one or more embodiments, the optical fiber is a light guide that constrains light, via total internal reflection, within, for example, a cylindrical path, which may include a circular or other shape cross section. Optical fibers are commonly used in optical telecommunications networks, but are also used to deliver high power laser light from a laser to a working optic. In one or more embodiments, the free space is an optically transparent or semi-transparent medium for sending optical power. Examples of free space include air or other gas, a vacuum, a liquid (e.g., water), and a transparent solid (e.g., a window).

A power receiver 16 receives the light via the transmission medium 14. In one or more embodiments, there is no conductive path between the power receiver 16 and the laser power transmitter 12. In one or more embodiments, optics (e.g., lenses, prisms) are provided at the power receiver 16 for conditioning the light, such as by shaping, splitting, reflecting, and/or refracting the light.

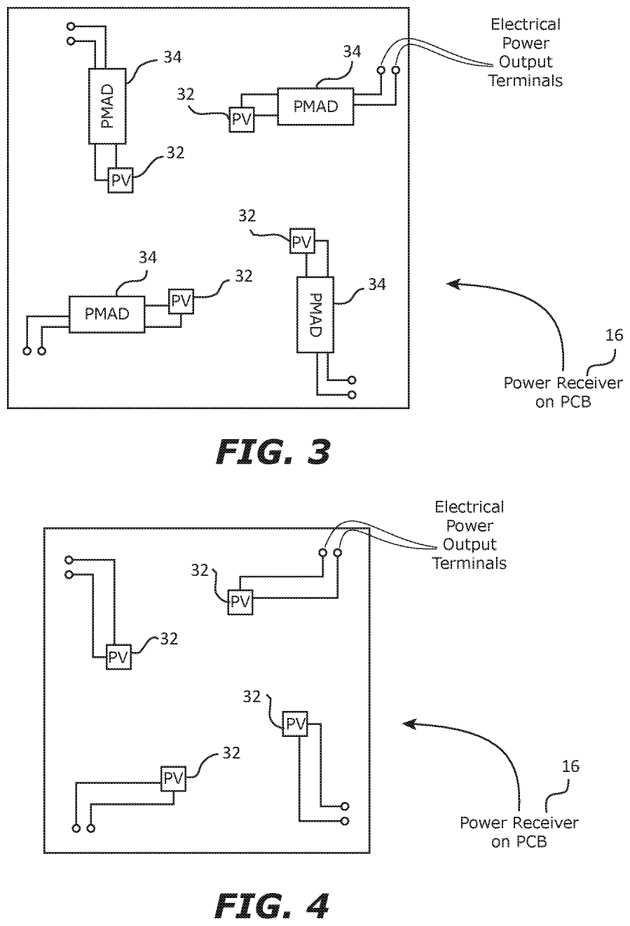

In one or more embodiments, the power receiver 16 includes photovoltaic (PV) modules (for example, as shown in FIGS. 3 and 4), which receive the light and, in response, output electric power. A PV module is a set of one or more photovoltaic (PV) cells which are electrically connected and produce a single electrical output. The PV cells in PV modules may be optionally connected to power management and distribution modules (aka PMADs), which might include maximum power point tracking (MPPT) and/or DC/DC converting and regulating electronics (for example, as shown in FIG. 3, and without PMADs in FIG. 4).

As defined herein, a receiver power leg is a PV module, along with maximum power point tracking (MPPT) and/or DC/DC for converting and regulating electronics, which together may be referred to as a PMAD (Power Management and Distribution). In one or more embodiments, the power receiver 16 includes one or more receiver power legs. The electric power generated by the PV modules is provided to a set of drivers which in turn uses the electric power to generate a drive signal that drives the electronic switches. Each PV module and all of the electronics, if any, after it in the power flow direction (for example, an MPPT and/or DC/DC converter) are electrically isolated from the other PV modules and their electronics, such that the switches can float at different voltages relative to each other.

FIGS. 3 and 4 illustrate the power receiver 16 according to embodiments disclosed herein. The power receiver 16 is a converter that converts a light beam emitted from the laser power transmitter 12 into an electrical signal for the drivers 18. The power receiver 16 includes PV modules 32 that are each configured to receive the light emitted from the laser power transmitter 12 through the transmission medium 14, and, in response, output electric power. In one or more embodiments, the electric power output from the PV modules is an electrical signal having electrical characteristics (e.g., amplitude, frequency, power level, etc.) corresponding to an electrical power signal received from the electrical power 10. The electric power generated by the PV modules 32 is provided to the set of drivers 18 which drives the electronic switches 20. As discussed above, in one or more embodiments, each PV module and all of the electronics, if any, after it in the power flow direction (for example, an MPPT and/or DC/DC converter) are electrically isolated from the other PV modules and their electronics, such that the switches 20 can float at different voltages relative to each other. In one or more embodiments, the electrical power output terminals of the power receiver 16 are electrically isolated from each other.

Electronic Switching elements may refer to one or more types of transistors, such as FETs (e.g., MOSFET, JFET) and IGBTs, by way of non-limiting example.

In one or more embodiments, as shown in FIG. 3, the power receiver 16 includes PMADs 34, and PV cells in the PV modules 32 are connected to the PMADs 34. The PMADs 34 are connected to output terminals of the power receiver 16. The PMADs 34 include maximum power point tracking (MPPT) and/or DC/DC converting and regulating electronics.

FIG. 4 is the power receiver 16 according to another embodiment disclosed herein. In contrast to the embodiment shown in FIG. 3, the power receiver 16 in FIG. 4 does not include PMADs 34, and the PV cells in the PV modules 32 are directly connected to output terminals of the power receiver 16. As discussed above, in one or more embodiments, each PV module and all of the electronics, if any, are electrically isolated from the other PV modules and their electronics, such that the switches 20 can float at different voltages relative to each other. In one or more embodiments, the electrical power output terminals of the power receiver 16 are electrically isolated from each other.

Returning to FIG. 1, a switch controller 22 sends the appropriate signals to each of the drivers 18 so that the drivers 18 drive electrical switching elements or switches 20 in the correct manner (for example, at a desired time). The switch controller 22 includes one or more processors, memory, and input/output connections for controlling drivers connected to switches 20. Each of the drivers 18 is electrically coupled to a respective switch 20, and is configured to control an operating state of the respective switch 20 (e.g., drive the respective switch to be in an open/on state or to be in a closed/off state). As an example, the switches 20 may each be controlled to output a substantially sinusoidal electrical waveform having a desired frequency and amplitude, and each waveform may be offset in phase from waveforms generated by other switches 20 of the optically-isolated VFD. In one or more embodiments, the switch controller 22 includes an input for receiving control signals, and is configured to control the drivers 18 to actuate a load based on the control signals.

The laser power transmitter 12 may include an electrical power converter, one or more laser drivers, one or more lasers, and a thermal management system to regulate the temperature of the lasers, a laser controller, and optics to shape the light. The thermal management system may be a passive or an active system. An active system may include a chiller or thermoelectric cooler.

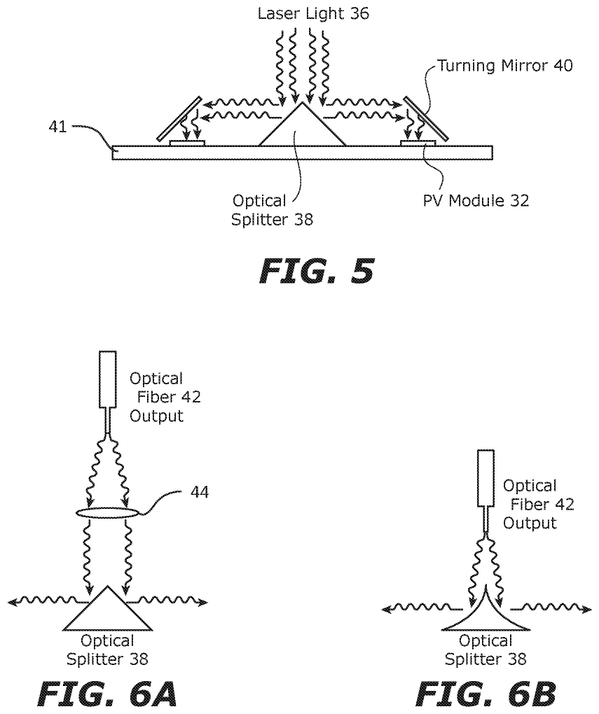

The laser power transmitter 12 is a converter that converts an electrical power signal received from the electrical power 10 into an optical light beam. In some embodiments, the laser power transmitter 12 includes one laser. FIG. 2 shows the laser power transmitter 12 according to an embodiment disclosed herein. The laser power transmitter 12 includes a laser controller 24 configured to control the laser 26 and thermal management system 25, the thermal management system 25 configured to regulate a temperature of the laser power transmitter 12, an electronic (laser) driver 26 configured provide a driving signal to the laser 28 to emit light, the laser 28 itself configured to emit light in response to receiving the driving signal, and optics 30 to shape or otherwise condition the light (e.g., shaping and/or focusing, which may be performed by reflecting and/or refracting the light) for transmission into the transmission medium 14 (or media in some implementations). In one or more embodiments, the light emitted from the laser 28 has optical characteristics (e.g., amplitude, frequency, modulation frequency, power level, and the like) corresponding to an electrical power signal received from the electrical power 10. The laser light emitted by the laser power transmitter 12, more specifically the laser 28, may be split (e.g., via optics) into separate beams before reaching the physically separate PV modules, such that each PV module receives light (for example, as shown in FIG. 5). Splitting may be performed in the laser power transmitter, or from one fiber to many fibers (in cases where optical fiber is used), or may be performed in the power receiver.

FIG. 5 shows a laser light being split into separate beams according to an embodiment disclosed herein. The incident laser light 36 in FIG. 5 may be from either free space or an optical fiber. In one or more embodiments, the optical element 38 labeled “optical splitter” is a reflecting element that splits the incident beam into a number of separate beams each directed in approximately radial directions. In one or more embodiments, as shown in FIG. 5, the optical element 38 is an N-sided pyramidal mirror (where N is an integer greater than 1). Optical designs other than a pyramidal mirror could be used instead to achieve the same effect. Although a single optical element is shown in FIG. 5, any number of optical elements may be used. In one or more embodiments, turning mirrors 40, which may be flat mirrors angled at roughly 45° relative to the incident light direction, are used to redirect the light at roughly a 90° angle towards the PV modules 32. The turning mirrors 40 may be controlled (e.g., by the switch controller 22) to appropriately direct or steer light to one or more corresponding PV modules 32. In one embodiment, as shown in FIG. 5, the PV modules 32, the optical splitters 38, and the turning mirrors 40 are positioned on a substrate 41, such as a Printed Circuit Board (PCB).

FIGS. 6A and 6B show embodiments of receiver optics, in a case where an optical fiber is a light source (e.g., in a cases where the transmission medium 14 is an optical fiber).

FIG. 6A shows receiver optics according to an embodiment disclosed herein. In the embodiment shown in FIG. 6A, light emitted from the laser power transmitter 12 is emitted via an optical fiber 42 (e.g., the transmission medium 14 is an optical fiber), and a lens 44 or other optical element is used to collimate the divergent light from the optical fiber 42. The optical splitter 38, which in this case is represented as an N-sided pyramidal mirror, splits the approximately collimated light out radially, towards PV modules 32 (for example, as shown in FIG. 5). In one or more embodiments, the lens 44 is included in the power receiver.

FIG. 6B shows receiver optics according to another embodiment disclosed herein. In FIG. 6B, light emitted from the laser power transmitter 12 is emitted via an optical fiber 42 (e.g., the transmission medium 14 is an optical fiber). However, in contrast to the embodiment shown in FIG. 6A, a lens is not used to collimate the divergent light from the optical fiber 42. Instead, the light is transmitted to the optical splitter 38 though free space. In this embodiment, the optical splitter 38 operates to both split and shape (for example, by collimating) the light received, in this example provided by a concave shape to each segment of the N-sided pyramidal mirror. By shaping the light, the optical element (shown as a lens) in FIG. 6A is eliminated, its functionality having been incorporated into the optical splitter. While the example shown uses reflective methods, other methods of splitting the light could be used, for example refractive methods, or a combination of methods.

In one or more embodiments, the PV modules 32 are all on a single Printed Circuit Board (PCB) (or direct bonded copper (DBC), or other “board”), as shown, for example, in FIGS. 3 and 4. The individual PV cells may have encapsulant or other insulating material on the connecting electrical wires to reduce the possibility of electrical discharge or corona connecting to them. Each PV module is physically separated from the other PV modules (and from the electrical wiring) by a distance adequate to prevent electrical arcing between the relative voltages in the application, or other electrical interference. The single PCB has multiple, electrically-isolated outputs.

In one or more embodiments, the laser power transmitter 12 includes more than one laser. In these embodiments, the light emitted from an individual laser may be directed to an individual PV module 32.

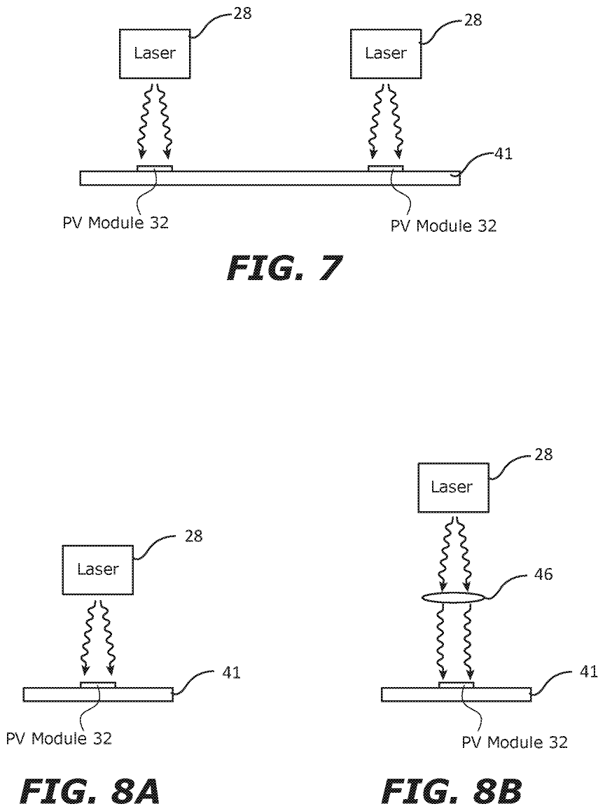

FIG. 7 shows the laser power transmitter 12 and the power receiver 16 according to another embodiment disclosed herein. In the embodiment shown in FIG. 7, the laser power transmitter 12 includes a plurality of lasers 28, and the power receiver 16 includes a plurality of PV modules 32. In one or more embodiments, a total number of lasers 28 in the laser power transmitter 12 is equal to a total number of PV modules 32 in the power receiver 16; and each of the lasers 28 transmit light onto a respective PV module 32. For example, as shown in FIG. 7, each of the two lasers 28 transmits light onto a respective PV module 32. Although two lasers and two PV modules are shown in FIG. 7, the laser power transmitter 12 may include any number of lasers, and the power receiver 16 may include any number of PV modules.

In one or more embodiments, the light travels directly from the laser to the PV module—for example, in cases where the beam divergence, PV size, and laser-to-PV spacing is such that no significant amount of light would be wasted and a high degree of energy transfer is achieved (e.g., greater than 95% optical efficiency). In another embodiment, the light from the laser may be collimated or otherwise shaped by one or more optical elements in order to project the light such that no significant amount of light is wasted at each PV module.

In one or more embodiments, a plurality of lasers may be implemented such that each of the lasers correspond to a separate PV module. In some embodiments, each laser may have its own fiber to go to its own PV module. The laser light might travel directly from the laser to the PV module without additional optical elements. For example, FIG. 8A is a laser and a PV module according to an embodiment disclosed herein. In the embodiment shown in FIG. 8A, the laser 28 emits light directly from the laser 28 to the PV module 32. Optical elements are not positioned between the laser 28 and the PV module 32.

In one or more embodiments, one or more optical elements are used to shape the laser light (for example, collimating it). For example, FIG. 8B is a laser and a PV module according to another embodiment disclosed herein. In the embodiment shown in FIG. 8B, the laser 28 emits light from the laser 28, through an optical element 46 (e.g., the lens 44), and to the PV module 32. In one or more embodiments, the optical element 46 collimates light transmitted from the laser 28.

In one or more embodiments, the laser power transmitter 12 and the power receiver 16 is jointly enclosed in a single housing. In some of these embodiments, the housing and any other materials that create a physical connection from the transmitter to the receiver would be non-conductive (e.g., electrically insulating). The transmitter and receiver may be sufficiently spaced apart to prevent electrical arcing or corona at the expected operating conditions.

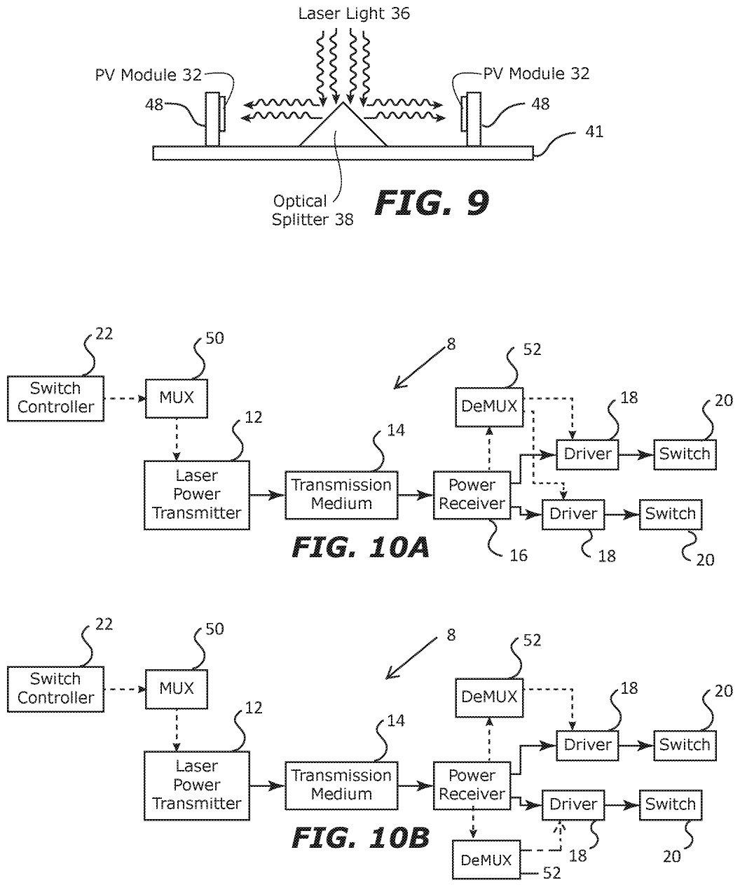

In one or more embodiments, light that has been split into multiple beams impinge directly on PV modules 32 that are oriented to catch the light, instead of relying on turning mirrors as shown, for example, in FIG. 5. In these embodiments, the PV modules 32 may be mounted on the carrier board (e.g., PCB) such that the PV modules 32 have a surface oriented transversely (e.g., perpendicular) to a surface of the main board plane. FIG. 9 shows an example of this type of embodiment.

FIG. 9 shows a laser light being split into separate beams according to an embodiment disclosed herein. Similar to the embodiment shown in FIG. 5, laser light 36 is directed towards the optical element 38, which then splits the incident last light into a number of separate beams. However, in contrast to the embodiment shown in FIG. 5, turning mirrors are not used to redirect the separate beams on to the PV modules 32. Instead, PV modules 32 are mounted on their own substrates 48 or sub-boards that extend from the surface of the substrate 41 or PCB main board and that are in turn mounted on the main board (PCB). In one or more embodiments, the substrate 41 extends in a first direction, and the substrates 48 extend in a second direction transverse to the first direction. Accordingly, the split beams impinge directly on to the PV modules 32.

The PV modules 32 include one or more photovoltaic cells. In one or more embodiments, a PV module 32 includes a single PV cell per module. In another embodiment, each of the PV modules 32 includes multiple PV cells. In one or more embodiments, the output voltage range of PV cells might be adequate to directly power a device, such as a driver and switch. In one or more embodiments, the PV cell output might be managed by a Maximum Power Point Tracker (MPPT) to extract maximum power. In one or more embodiments, the output (with or without an MPPT) of the PV cell is converted and/or regulated by a DC/DC converter to match the desired electrical characteristics (e.g., voltage level, frequency, waveform) for operating (e.g., powering) a device coupled to the driver and switch (e.g., VFD).

FIGS. 10A and 10B illustrate a laser power beaming system 8 according to another embodiment disclosed herein. In this embodiment, control signals from the switch controller 22 for all of the drivers 18 are multiplexed by a multiplexer 50 into a data stream that is transmitted using the laser power transmitter 12 as discussed above by modulating the laser 28 (for example, by varying the light intensity) in such a way that is detectable at the power receiver 16 and can be decoded by a demultiplexer 52. In one or more embodiments, shown in FIG. 10A the multiplexer 50 selects a control signal from the control signals from the switch controller 22. The demultiplexer 52 then routes the control signals to each of the drivers 18. In one or more other embodiments, shown in FIG. 10B the multiplexer 50 selects a control signal from the control signals from the switch controller 22. Multiple demultiplexers 52 then each route a control signal to a respective driver 18. In one or more different embodiments (not shown), multiple multiplexers 50 (each having a laser) each select a control signal from the switch controller 22. The multiple multiplexers 50 send their respective control signals to multiple demultiplexers 52 that each route a control signal to a respective driver 18.

In other embodiments, if multiple lasers are used separately for each receiver power leg (as shown, for example, in FIG. 7), the controller data for a specific driver may be multiplexed with the power for that specific receiver power leg. In one or more embodiments, a receiver power leg is a PV module, along with maximum power point tracking (MPPT) and/or DC/DC converting and regulating electronics, which together may be referred to as a PMAD (Power Management and Distribution), if any, and the electrical power output terminal or connector. In one or more embodiments, the power receiver 16 includes one or more receiver power legs.

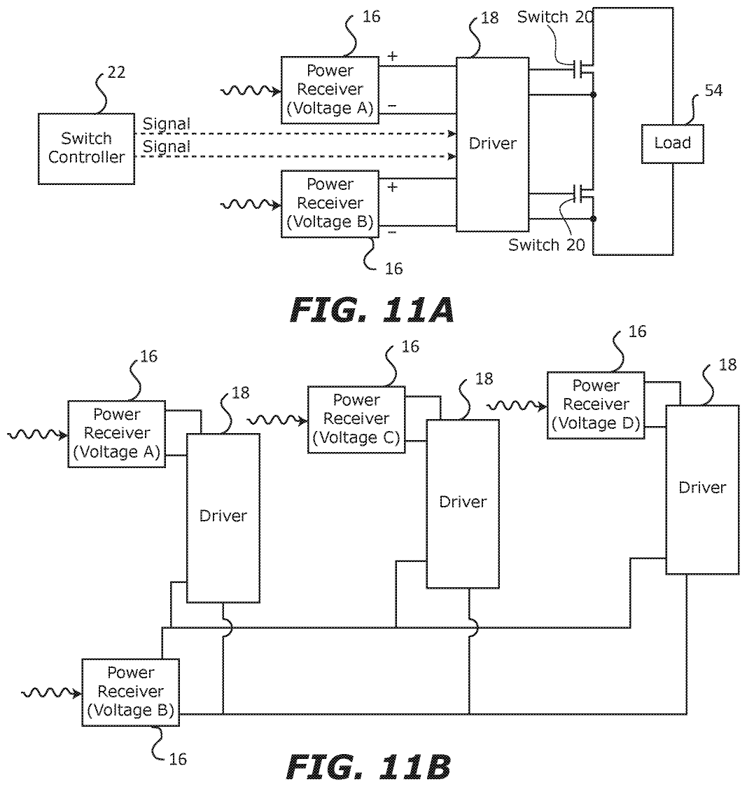

FIGS. 11A and 11B show examples of the wiring for drivers and switches for the laser power beaming system 8.

FIG. 11A is a driver and a switch according to an embodiment disclosed herein. In FIG. 11A, two power receivers 16 are shown. One of the power receivers 16 is set or referenced to voltage level A, and the other of the power receivers 16 is set or referenced to voltage level B. In one or more embodiments, the voltage level A and the voltage level B are equal to each other. In one or more embodiments, the voltage level A and the voltage level B are different voltage levels. The power receivers 16 provide power to independent channels within the driver 18 (which may be an IC), which each drive a separate electronic switch 20. The switch controller 22 provides one or more control signals to the driver 18 that determines when each switch 20 is being turned on or off. In one or more embodiments, the lower voltage from each of the power receivers 16 (labeled with a “-” symbol in FIG. 11A) may be referenced to the lower voltage side of the switch 20 that corresponds to that power receiver 16. The load 54 may be any type of load, component, or device electrically coupled to the switches 20. In one or more embodiments, the switches 20 actuate and operate the load 54.

FIG. 11B is drivers and switches according to another embodiment disclosed herein. In FIG. 11B, a possible configuration is shown for an inverter type application (for example, a variable frequency drive). In this embodiment, three “legs” of the inverter (each leg corresponding to one driver 18) operate at different voltages relative to each other, and so three electrically isolated power receivers 16 provide power for each driver (the switches and other connections, such as the switch controller inputs, are not shown in FIG. 11B but are similar to what is shown in FIG. 11A). Since the lower voltage end of each inverter leg all go to the same voltage (in this case, the power receiver 16 labeled as Voltage B is referenced to this lower output voltage, and which may be ground), a single power receiver 16 is provided to power the lower voltage side of all three drivers.

Photovoltaic cells disclosed herein may be single junction, double junction, or higher-number multi-junction type of cells. The junctions can be stacked vertically or arranged adjacent horizontally. The output open circuit voltage and maximum power point voltage of a PV cell is approximately the respective voltage of a single junction multiplied by the total number of junctions. The open circuit voltage of a single junction depends on the type of photovoltaic material and other design factors, but may be in the range of 0.6V-1.2V in some applications.

The receiver power legs disclosed herein may be physically spaced apart from each other, and may also have encapsulant or other insulation. These features facilitate isolation between different receiver power legs and may prevent electrical arcing, corona, or other electromagnetic interference between the legs. In different applications, the difference in electric signals transmitted through separate receiver power legs depends on the desired application. Voltage difference between legs may be hundreds of volts, for example 220V, 500V, 1,000V, several thousand volts, or other voltage differences.

The configuration of the VFD, such as the number of receiver power legs, may depend on the type of device to be connected to an output of the optically-isolated drivers and switches. In some embodiments, the VFD may be configured to operate smaller devices having a single input and that consume less than one kilowatt of power (e.g., single phase motor). In some embodiments, the VFD may be configured to operate more substantial devices having a plurality of inputs and consuming greater than one kilowatt of power (e.g., three-phase motors).

In some embodiments, each receiver power legs may have voltage and/or current sensors which may provide feedback to the switching controller for error correction, controlling timings between outputs, and the like.

Certain words and phrases used in the present disclosure are set forth as follows. The terms “include” and “comprise,” as well as derivatives thereof, mean inclusion without limitation. The term “or,” is inclusive, meaning and/or. The phrases “associated with” and “associated therewith,” as well as derivatives thereof in all grammatical forms, may mean to include, be included within, interconnect with, contain, be contained within, connect to or with, couple to or with, be communicable with, cooperate with, interleave, juxtapose, be proximate to, be bound to or with, have, have a property of, or the like. The term “controller” means any device, system, or part thereof that controls at least one operation, such a device may be implemented in hardware, firmware, or software, or some combination of at least two of the same. The functionality associated with any particular controller may be centralized or distributed, whether locally or remotely. Additionally, reference to the term “figure” may actually refer to multiple figures, e.g., reference to FIG. 11 may refer to FIGS. 11A and 11B. Other definitions of certain words and phrases may be provided within this patent document. Those of ordinary skill in the art will understand that in many, if not most instances, such definitions apply to prior as well as future uses of such defined words and phrases.

Where one or more figures included in the present disclosure illustrates a data flow diagram, the illustrated process is a non-limiting process that may be used by various embodiments. In this regard, each described process may represent a module, segment, or portion of software code, which comprises one or more executable instructions for implementing the specified logical function(s). It should also be noted that in some implementations, the functions noted in the process may occur in a different order, may include additional functions, may occur concurrently, and/or may be omitted.

Processors may include central processing units (CPU's), microcontrollers (MCU), digital signal processors (DSP), application specific integrated circuits (ASIC), and the like. The processors interchangeably refer to any type of electronic control circuitry configured to execute programmed software instructions. The programmed instructions may be high-level software instructions, compiled software instructions, assembly-language software instructions, object code, binary code, micro-code, or the like. The programmed instructions may reside in internal or external memory or may be hard-coded as a state machine or set of control signals. According to methods and devices referenced herein, embodiments describe software executable by the processor and operable to execute certain ones of the method acts.

As known by one skilled in the art, a computing device has one or more memories, and each memory comprises any combination of volatile and non-volatile computer-readable media for reading and writing. Volatile computer-readable media includes, for example, random access memory (RAM). Non-volatile computer-readable media includes, for example, read only memory (ROM), magnetic media such as a hard-disk, an optical disk drive, a floppy diskette, a flash memory device, a CD-ROM, and/or the like. In some cases, a particular memory is separated virtually or physically into separate areas, such as a first memory, a second memory, a third memory, and the like. In these cases, it is understood that the different divisions of memory may be in different devices or embodied in a single memory. The memory in some cases is a non-transitory computer medium configured to store software instructions arranged to be executed by a processor.

The computing devices illustrated herein may further include operative software found in a conventional computing device such as an operating system or task loop, software drivers to direct operations through I/O circuitry, networking circuitry, and other peripheral component circuitry. In addition, the computing devices may include operative application software such as network software for communicating with other computing devices, database software for building and maintaining databases, and task management software where appropriate for distributing the communication and/or operational workload amongst various processors. In some cases, the computing device is a single hardware machine having at least some of the hardware and software listed herein, and in other cases, the computing device is a networked collection of hardware and software machines working together in a server farm to execute the functions of one or more embodiments described herein. Some aspects of the conventional hardware and software of the computing device are not shown in the figures for simplicity.

Database structures, if any are present in the various embodiments, may be formed in a single database or multiple databases. In some cases hardware or software storage repositories are shared amongst various functions of the particular system or systems to which they are associated. A database may be formed as part of a local system or local area network. Alternatively, or in addition, a database may be formed remotely, such as within a “cloud” computing system, which would be accessible via a wide area network or some other network.

Input/output (I/O) circuitry and user interface (UI) modules include serial ports, parallel ports, universal serial bus (USB) ports, IEEE 802.11 transceivers and other transceivers compliant with protocols administered by one or more standard-setting bodies, displays, projectors, printers, keyboards, computer mice, microphones, micro-electro-mechanical (MEMS) devices such as accelerometers, and the like.

Buttons, keypads, computer mice, memory cards, serial ports, bio-sensor readers, touch screens, and the like may individually or in cooperation be useful to an operator of various embodiments. The devices may, for example, input control information into the system. Displays, printers, memory cards, LED indicators, temperature sensors, audio devices (e.g., speakers, piezo device, etc.), vibrators, and the like are all useful to present output information to the operator of various embodiments. In some cases, the input and output devices are directly coupled or otherwise electronically coupled to a processor or other operative circuitry. In other cases, the input and output devices pass information via one or more communication ports (e.g., RS-232, RS-485, infrared, USB, etc.)

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, the technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein.

As used in the present disclosure, the term “module” refers to an application specific integrated circuit (ASIC), an electronic circuit, a processor and a memory operative to execute one or more software or firmware programs, combinational logic circuitry, or other suitable components (i.e., hardware, software, or hardware and software) that provide the functionality described with respect to the module.

Reference throughout this specification to “one embodiment” or “an embodiment” and variations thereof means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

This application claims the benefit of priority to U.S. Provisional Application No. 62/901,107 filed Sep. 16, 2019, the entirety of which is incorporated by reference herein.

1. A device comprising:
a plurality of electrical switching elements;
a plurality of drivers electrically coupled to the plurality of electrical switching elements, the plurality of drivers configured to change operating states of the plurality of electrical switching elements; and
a converter that includes a plurality of photovoltaic (PV) modules configured to receive a plurality of light beams and convert the plurality of light beams into electrical signals for the plurality of drivers, the plurality of PV modules being electrically isolated from one another.

2. The device of claim 1, further comprising:
a laser power transmitter configured to:
receive an electrical power signal; and
in response to receiving the electrical power signal, transmit the plurality of light beams to the converter.

3. The device of claim 2, wherein the plurality of light beams have optical characteristics corresponding to the electrical power signal.

4. The device of claim 2, further comprising:
a transmission medium configured to transmit the plurality of light beams from the laser power transmitter to the converter.

5-6. (canceled)

7. The device of claim 1, wherein each member of the plurality of PV modules includes at least one photovoltaic cell configured to convert light into electricity, and wherein the device further includes a plurality of power management and distribution modules electrically coupled to the plurality of PV modules.

8. The device of claim 1, further comprising:
a laser power transmitter configured to receive an electrical power signal, and transmit a light beam in response to receiving the electrical power signal; and
an optical splitter configured to:
receive the transmitted light beam; and
split the transmitted light beam into the plurality of light beams.

9. (canceled)

10. The device of claim 8, further comprising:
an optical element configured to collimate the transmitted light beam.

11. The device of claim 8, wherein the optical splitter is configured to collimate at least one member of the plurality of transmitted light beams.

12-16. (canceled)

17. A power receiver, comprising:
a plurality of photovoltaic (PV) receiver legs, wherein:
each PV receiver leg includes a PV module configured to convert an optical input to an electrical output; and
each member of the plurality of PV receiver legs is electrically isolated from each other member of the plurality.

18. The power receiver of claim 17, wherein each PV module comprises at least one PV cell.

19. The power receiver of claim 17, wherein at least one PV module comprises a plurality of PV cells.

20. The power receiver of claim 17, further comprising an optical element configured to:
receive an incoming light beam; and
direct at least a portion of the received incoming light beam onto a member of the plurality of PV receiver legs.

21. The power receiver of claim 20, wherein the optical element includes a beam splitter configured to direct a portion of the incoming light beam onto each member of the plurality of PV receiver legs.

22-23. (canceled)

24. The power receiver of claim 17, further comprising an optical fiber configured to direct an optical input toward one or more members of the plurality of PV receiver legs.

25-27. (canceled)

28. The power receiver of claim 17, wherein at least one of the PV receiver legs includes a power management and distribution (PMAD) component.

29. A power transmission system, comprising:
the power receiver of claim 17; and
a light source configured to provide an optical input to the power receiver.

30. The power transmission system of claim 29, further comprising a transmission element configured to conduct the optical input from the light source to the power receiver.

31. (canceled)

32. The power transmission system of claim 29, further comprising a multiplexer configured to encode a control signal into the optical input.

33. The power transmission system of claim 32, further comprising a controller configured to create the control signal for encoding by the multiplexer.

34. The power transmission system of claim 32, wherein at least one member of the plurality of PV receiver legs includes a demultiplexer configured to extract the encoded control signal from the electrical output of its PV module.

35. The power transmission system of claim 34, wherein each member of the plurality of PV receiver legs includes a demultiplexer configured to extract the encoded control signal from the electrical output of its PV module.

36. The power transmission system of claim 35, wherein each demultiplexer is configured to identify a portion of the encoded control signal that pertains to its own PV receiver leg.

37. The power transmission system of claim 34, further comprising a driver for controlling an electrical component, wherein the driver is configured to receive the extracted control signal from the demultiplexer and to use the received control signal to drive the electrical component.

38-48. (canceled)
